(19) United States
(12) Patent Application Publication
(10) Pub. No.: US 2009/0008626 A1
(43) Pub. Date: Jan. 8, 2009

(54) Optoelectronic device

(75) Inventors: Tzong-Liang Tsai, Taichung City (CN); Yu-Chu Li, Taichung City (CN)

Correspondence Address: REED SMITH LLP, Suite 1400, 3110 Fairview Park Drive, Falls Church, VA, 22042, US

(73) Assignee: Huga Optotech Inc.

(21) Appl. No.: 12/000,610

(22) Filed: Dec. 14, 2007

(30) Foreign Application Priority Data
Jul. 6, 2007 (CN) 096124608

(51) Int. Cl. H01L 29/06; H01L 33/00

(52) U.S. Cl. 257/13; 257/96; 257/E29.168; 257/E33.014

(57) ABSTRACT

The present invention provides an optoelectronic device which includes a first electrode, a substrate on the first electrode; a buffer layer on the substrate, in which the buffer layer includes a first gallium nitride based compound layer on the substrate, a second gallium nitride based compound layer, and a II-V group compound layer between the first gallium nitride based compound layer and the second gallium nitride based compound layer; a first semiconductor conductive layer on the buffer layer; an active layer on the first semiconductor conductive layer, in which the active layer is an uneven Multi-Quantum Well; a semiconductor conductive layer on the active layer; a transparent layer on the second semiconductor conductive layer; and a second electrode on the transparent layer.

### BACKGROUND OF THE INVENTION

1. Field of the Invention

The present invention is related to an optoelectronic device, especially related to an optoelectronic device having a buffer layer with V-II group compound layer.

2. Background of the Related Art

The crystal property of GaN compound needs to be improved for providing a solution on the issue of lattice matching between sapphire and GaN in a light-emitting layer. In U.S. Pat. No. 5,122,845, shown in FIG. 1, an AlN-based buffer layer 101 is formed between a substrate 100 and GaN compound layer 102, which is microcrystal or polycrystal to improve crystal mismatching between the substrate 100 and the GaN compound layer 102. In U.S. Pat. No. 5,290,393, shown in FIG. 2, an optoelectronic device is a GaN-based compound semiconductor layer 202, such as GaₓAl₁₋ₓN (0<x≦1). However, during the formation of a compound semiconductor layer 202 on a substrate 200 by epi-growth, the lattice structure on the surface of the substrate 200 may influence the quality of a sapphire device. Thus, a buffer layer 201, such as GaₓAl₁₋ₓN, is between the substrate 200 and the compound semiconductor layer 202 to improve lattice mismatching. Furthermore, in U.S. Pat. No. 5,929,466 or 5,909,040, shown in FIG. 3, an AlN layer 301 as a first buffer layer is formed on a substrate 300, an InN layer 302 as a second buffer layer is on the AlN layer 301, which may improve lattice mismatching near the substrate 300. However, there is only limited optoelectronic effect in those prior arts. Thus, the buffer layer of an optoelectronic device in the present invention is made of V-II group compound layer on a base and associated with an uneven active layer for improvement on the brightness of light source derived from a light-emitting zone. Accordingly, the optoelectronic effect of the optoelectronic device may be enhanced.

### SUMMARY OF THE INVENTION

In order to solve the problems mentioned above, one of objects of the present invention provides an epi-stack structure. A V-II group compound layer is added in a buffer layer for quality improvement of an epi-structure and enhance of optoelectronic efficiency of the whole optoelectronic device.

Another object of the present invention provides an epi-stack structure. A V-II group compound layer is added in a buffer layer associated with a multiple quantum well (MQW) having an uneven surface for enhance of optoelectronic efficiency of the whole optoelectronic device.

Accordingly, the present invention provides a stacked structure for an optoelectronic device, which includes: a substrate; a buffer layer including a first gallium nitride based compound layer on the substrate; a second gallium nitride based compound layer; and a V-II group compound layer between the first gallium nitride based compound layer and the second gallium nitride based compound layer. Moreover, a first semiconductor conductive layer is on the buffer layer; an active layer with a multi quantum well (MQW) on the first semiconductor conductive layer; and a second semiconductor conductive layer on the active layer; in which a plurality of microparticles are distributed between the first semiconductor conductive layer and the active layer to form an uneven surface of the multi quantum well.

Accordingly, the present invention provides an optoelectronic device, which includes a first electrode; a substrate on the first electrode; a buffer layer on the substrate. The buffer layer includes a first gallium nitride based compound layer on the substrate; a second gallium nitride based compound layer; and a V-II group compound layer between the first gallium nitride based compound layer and the second gallium nitride based compound layer. Moreover, a first semiconductor conductive layer is on the buffer layer; a second semiconductor conductive layer; an active layer between the first semiconductor conductive layer and the second semiconductor conductive layer; a transparent conductive layer on the second semiconductor conductive layer; and a second electrode on the transparent conductive layer.

### BRIEF DESCRIPTION OF THE DRAWINGS

FIG. 1 is a cross-sectional diagram illustrating an optoelectronic semiconductor device in accordance with a prior art.

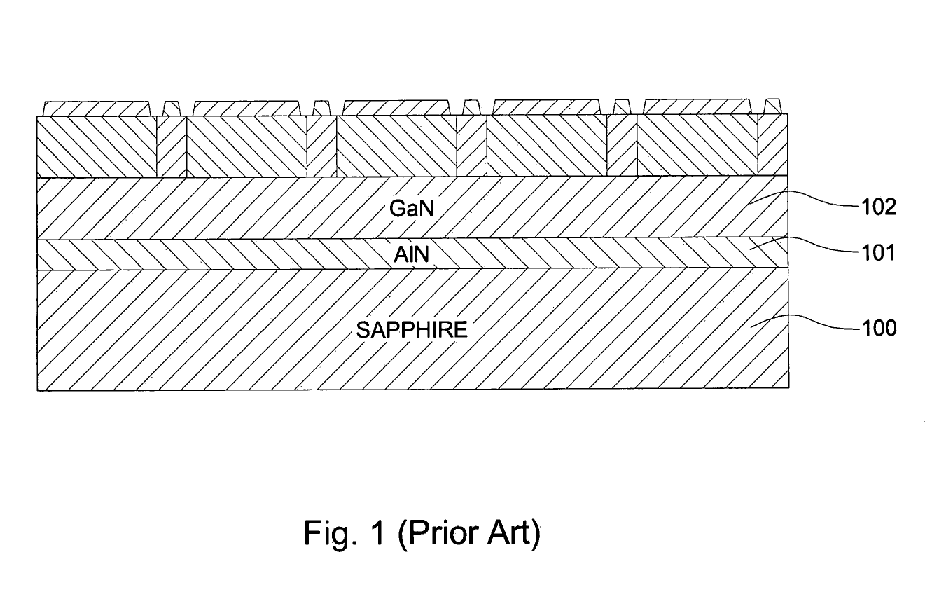

FIG. 2 is a cross-sectional diagram illustrating an epitaxy wafer in accordance with a prior art.

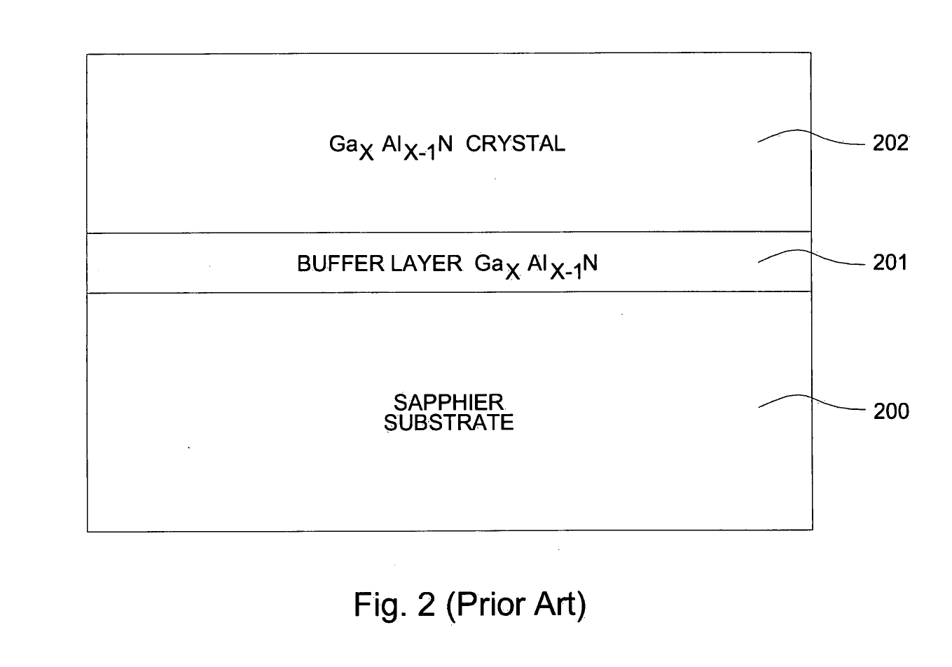

FIG. 3 is a cross-sectional diagram illustrating an epitaxy wafer in accordance with a prior art.

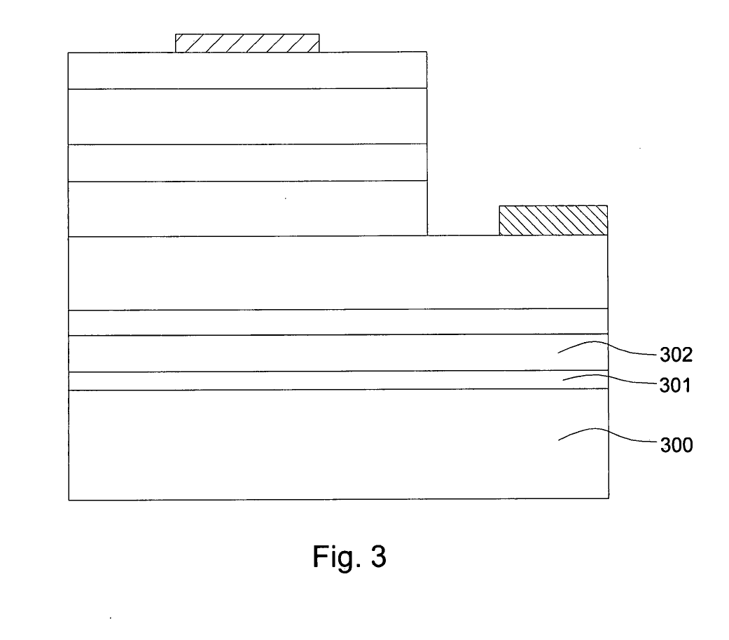

FIG. 4 is a cross-sectional diagram illustrating a semiconductor structure with a multi strain releasing layer in accordance with the present invention.

FIG. 5 is a schematically cross-sectional diagram illustrating a multi strain releasing layer of an optoelectronic device in accordance with the present invention.

FIG. 6 is a schematically cross-sectional diagram illustrating a multi strain releasing layer of an optoelectronic device in accordance with the present invention.

### DETAILED DESCRIPTION OF THE INVENTION

The present invention provides an optoelectronic device.

Following illustrations describe detailed optoelectronic device for understanding the present invention. Obviously, the present invention is not limited to the embodiments of optoelectronic device; however, the preferable embodiments of the present invention are illustrated as followings. Besides, the present invention may be applied to other embodiments, not limited to ones mentioned.

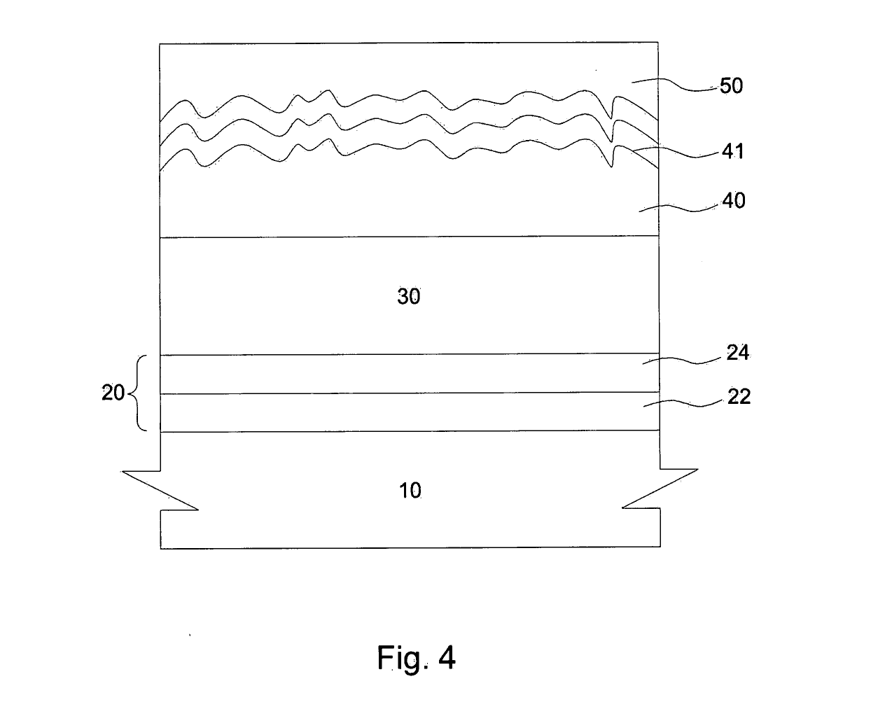

FIG. 4 is a cross-sectional diagram illustrating a semiconductor structure with an epi-structure in accordance with the present invention. The semiconductor structure of includes a substrate 10 of sapphire in MOVPE. A buffer layer 20, such as a multi-strain releasing layer, is formed on the substrate 10. In the embodiment, the buffer layer 20 has a compound layer 22 and a V-II group compound layer 24. The compound layer 22 is on the substrate 10 and gallium nitride based, such as AlGaN. For the substrate 10, it is selected from the group consisting of: sapphire, MgAl₂O₄, GaN, AlN, SiC, GaAs, AlN, GaP, Si, Ge, ZnO, MgO, LAO, LGO and glass material.

The V-II group compound layer 24 is formed on the compound layer 22, which has the material of II group selected from the group consisting of: Be, Mg, Ca, Sr, Ba, Ra, Zn, Cd and Hg, and the material of V group selected from the group consisting of: N, P, As, Sb and Bi. Accordingly, the V-II group compound layer 24 may be made of the aforementioned materials combined.

In the embodiment, for the V-II group compound layer 24, an Mg-contained precursor such as DCp₂Mg(bis(cyclopentadienyl)Magnesium) or Bis(methylcyclopentadienyl)Magnesium is put in a reactive chamber which NH₃ is leaded in. Then, an MgₓN_{y} layer is formed by MOCVD. Thus, the MgₓN_{y} layer of the thickness 10 Angstroms, which is as the V-II group compound layer 24, is located on the gallium nitride based compound layer 22 and has a roughness smaller than 10 nanometers. In a preferred embodiment, the V-II group compound layer 24 has preferable roughness of about 2 nanometers to continuously grow on the compound layer 22 such as P-type material. Furthermore, the V-II group compound layer 24 has band-gap energy smaller than a conventional III-V group compound. For example, the material of V-II group compound is, such as Zn₃As₂ with the band-gap energy of 0.93 eV, Zn₃N with the band-gap energy of 3.2 eV, Zn₃P₃ with the band-gap energy of 1.57 eV, and Mg₃N₂ with the band-gap energy of 2.8 eV. However, the conventional III-V group compound, such as GaN, has the band-gap energy of 3.34 eV. Accordingly, the V-II group compound layer 24 has better ohmic contact.

Next, an epi-stack structure 30 is formed on the buffer layer 20, which includes a first semiconductor conductive layer 30 on the buffer layer 20, an active layer 40 on the first semiconductor conductive layer 30, and a second semiconductor conductive layer 50 on the active layer 40. The first semiconductor conductive layer 30 and the second semiconductor conductive layer 50 are made of III-V group compound of nitride-based material. The active layer 40 can be one of group consisting of Double Hetero-junction (DH), single quantum well structure and Multi Quantum Well (MQW) structure. Furthermore, the first semiconductor conductive layer 30 and the second semiconductor conductive layer 50 have different electric for example, the first semiconductor conductive layer 30 of N-type associated with the second semiconductor conductive layer 50 of P-type.

Next, in a preferred embodiment, alternatively, a plurality of microparticles made of one or more hetero material may be added in the reactive chamber to be randomly distributed on the first gallium nitride based compound layer 30. It is noted that the kind and amount of the material for the microparticles are not limited herein. Any hetero material different from the first gallium nitride based compound layer 30 may be used. For example, in the case of GaN for the first gallium nitride based compound layer 30, the hetero material may be one in III group including B, Al, Ga, In or Ti, or II group including Be, Mg, Ca, Sr, Ba or Ra, or V group including N, P, As, Sb, Bi, or VI group including O, S, Se, Te, or V-III group, VI-II group or V-II group, such as Mg₃N₂ or SiNx.

Next, a MQW layer 40 is formed on the first gallium nitride based compound layer 30 that is covered by the hetero material. The hetero material may speed up or slow down the growth of MQW layer 40, thus an uneven surface 41 is formed near the position in the shape of cavity of the hetero material of the MQW layer 40. There are continuous or discontinuous dunes in different height and width for the MQW layer 40. The uneven surface of the MQW layer 40 has a cross-sectional area of the ratio of width and height in the range of 3:1 to 1:10 and roughness Ra in the range from 0.5 to 50 nanometers, preferred from 30 to 40 nanometers.

Moreover, in addition of sapphire with C, M, R or A main surface, the substrate 10 may be made of insulating material like MgAl₂O₄, SiC(containing 6H, 4H, 3C), GaAs, AlN, GaN, GaP, Si, ZnO, MgO, LAO, LGO or glass material. The MQW layer 40 with the uneven surface is made of a material selected from the group consisting of AlN, GaN, InN, AlGaN, InGaN and InAlGaN. It is noted that an active layer may be the MQW layer 40 with the uneven surface, or a quantum well layer or GaInN.

Next, referring to FIG. 4, a second semiconductor conductive layer 50 is formed on the MQW layer 40 (active layer) to perform an epi-stack structure of an optoelectronic device. The active layer is formed between N-type and P-type of semiconductor conductive layers. Electrons and electric holes may be driven to the active layer 40 to recombine and emit light when bias voltage is applied to the N-type and P-type of semiconductor conductive layers. Thus, the epi-stack structure of the optoelectronic device is not limited to the first gallium nitride based compound layer 30 of N-type or the second gallium nitride based compound layer 50 of P-type, and any suitable types may be used. In the case of the second gallium nitride based compound layer 50 of P-type, the first gallium nitride based compound layer 30 is P-type, reversely too. Moreover, the epi-stack structure of the optoelectronic device may be used as one basic epi-structure of LED, laser, photodetector, or VCSEL.

It is noted that different light may be emitted by the MQW layer of active layer 40 with various materials in combination of various percents, such as ultraviolet, visible light or infra red light. For example, P, As, or PAs compound may be added in the compound material of the active layer 40 to emit red, yellow or infra red light. Nitrogen may be added in the compound material of the active layer 40 to emit blue, green or ultraviolet light.

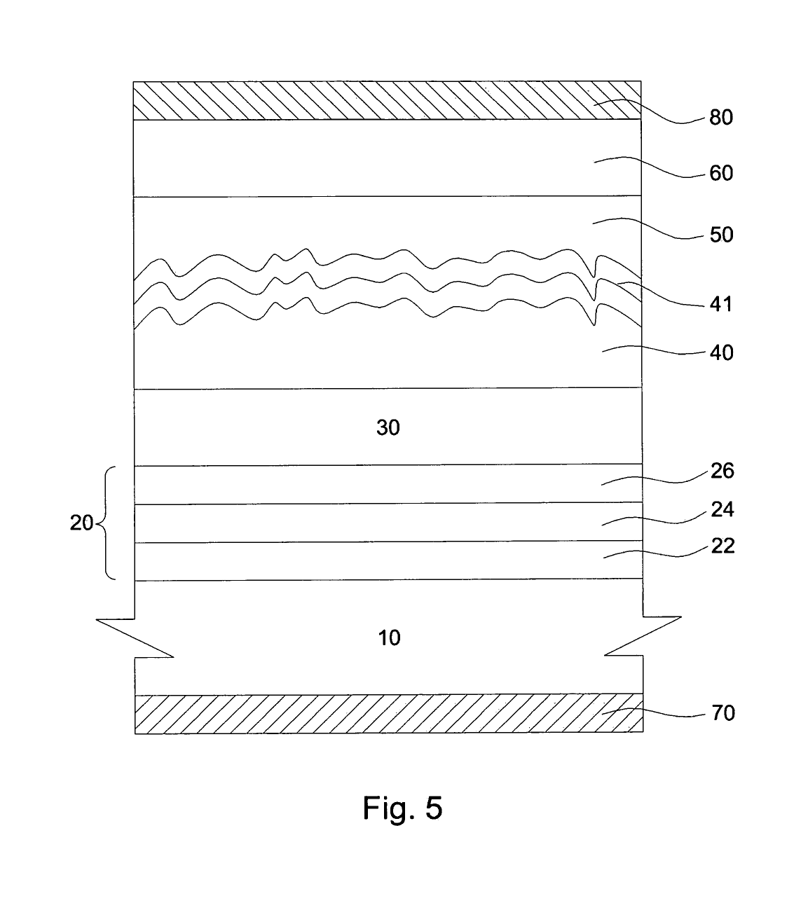

FIG. 5 is a schematically cross-sectional diagram illustrating an epi-structure of an optoelectronic device in accordance with the present invention. The forming method, structure and characteristics for the substrate 10 and the first semiconductor conductive layer 30, active layer 40 and the second semiconductor conductive layer 50 are same as ones in FIG. 4, which are not repeatedly illustrated herein. In FIG. 5, the optoelectronic device includes: a substrate 10, a buffer layer 20, an epi-stack structure (30, 40, and 50), a transparent conductive layer 60, a first electrode 70 and a second electrode 80. The buffer layer 20 is formed on the substrate 10. The epi-stack structure (30, 40, and 50) is formed on the buffer layer 20. The transparent conductive layer 60 is formed on the epi-stack structure (30, 40, and 50). The first electrode 70 is formed on the substrate 10 and the second electrode 80 is on the transparent conductive layer 60.

In the embodiment, from the buffer layer 20 to top, the epi-stack structure (30, 40, and 50) has a first semiconductor conductive layer 30, the active layer 40 and the second semiconductor conductive layer 50. It is noted that the buffer layer 20 on the substrate 10 includes a first gallium nitride based compound layer 22, V-II group compound layer 24 and a second gallium nitride based compound layer 26. The first gallium nitride based compound layer 22 is selected from the group consisting of: AlInGaN, InGaN, AlGaN and AlInN. The second gallium nitride based compound layer 26 is an AlGaN or GaN layer.

Moreover, the V-II group compound layer 24 includes a material of II group selected from the group consisting of: Be, Mg, Ca, Sr, Ba, Ra, Zn, Cd and Hg, and a material of V group selected from the group consisting of: N, P, As, Sb and Bi. The buffer layer 20, which is a multi-strain releasing layer structure including first gallium nitride based compound layer 22, V-II group compound layer 24, and second gallium nitride based compound layer 26, may be configured to be an initial layer for a sequential epi-stack structure (30, 40, and 50) by epi-growth method. Furthermore, there is good lattice match between the buffer layer 20 and first semiconductor conductive layer 30 to form nitride semiconductor structure in good qualities.

In the embodiment, first, an epitaxy wafer, which performs the formation of the epi-stack structure (30, 40, and 50) on the buffer layer 20, is moved out from a reactor chamber of room temperature. Next, a mask pattern is transferred to the second semiconductor conductive layer 50 of the epi-stack structure (30, 40, and 50) and then performed by reactive ion etching. Next, the transparent conductive layer 60 covers over the second semiconductor conductive layer 50 and has a thickness of about 2500 Angstroms. The material of the transparent conductive layer 60 is selected from the groups consisting of: Ni/Au, NiO/Au, Ta/Au, TiWN, TN, Indium Tin Oxide, Chromium Tin Oxide, Antinomy doped Tin Oxide, Zinc Aluminum Oxide and Zinc Tin Oxide.

Next, the second electrode 80 forms on the transparent conductive layer 60 and has a thickness of 2000 um. In the embodiment, the second semiconductor structure 50 is a P-type nitride semiconductor layer, and the second electrode 80 may be Au/Ge/Ni, Ti/Al, Tl/Al/Ti/Au or Cr/Au alloy or combination thereof. Finally, the first electrode 70 forms on the substrate 10, such as Au/Ge/Ni, Ti/Al, Tl/Al/Ti/Au, Cr/Au alloy or W/Al alloy. It is noted that the first electrode 70 and the second electrode 80 are formed by suitable conventional methods, which are not mentioned herein again.

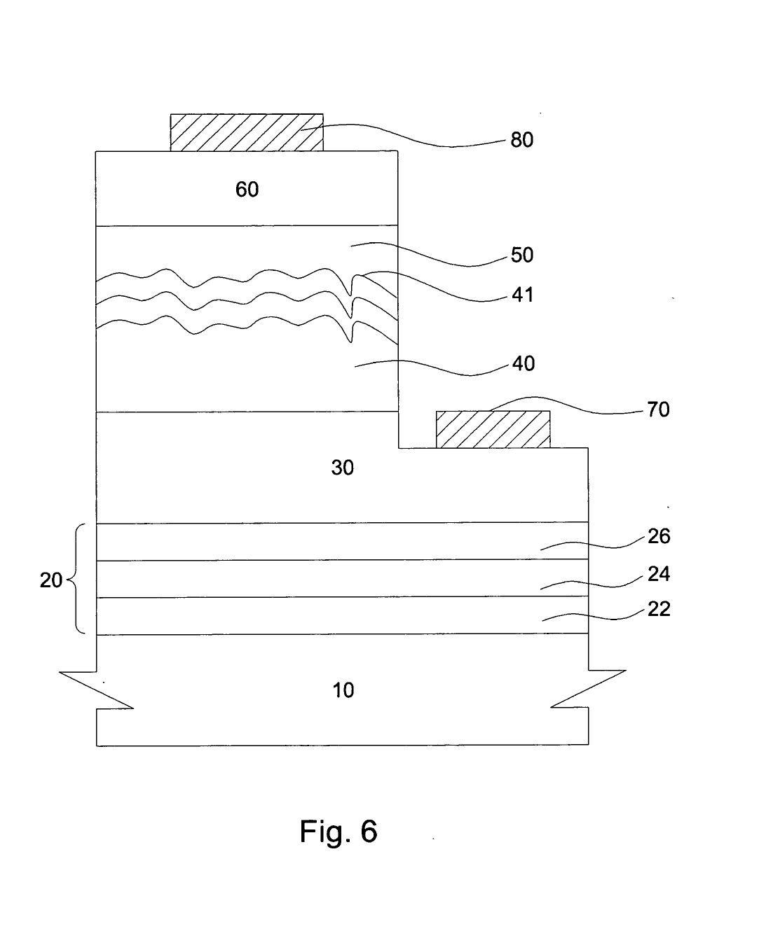

Next, FIG. 6 is a schematically cross-sectional diagram illustrating an epi-stack structure of an optoelectronic device in accordance with the present invention. In the embodiment, the forming method, structure and characteristics for the substrate 10 and the first semiconductor conductive layer 30, active layer 40 and the second semiconductor conductive layer 50 are same as ones in FIG. 4, which are not repeatedly illustrated herein. In FIG. 6, the optoelectronic device includes: a substrate 10, a buffer layer 20 on the substrate 10, an epi-stack structure (30, 40, and 50) on the buffer layer 20, a transparent conductive layer 60, a first electrode 70 and a second electrode 80. The buffer layer 20 is formed on the substrate 10. The epi-stack structure (30, 40, and 50) has a first portion and a second portion away from each other, wherein the transparent conductive layer 60 is on the first portion, the first electrode 70 on the second portion and the second electrode 80 on the transparent conductive layer 60.

In the embodiment, after the formation of the epi-stack structure, a portion of the second semiconductor conductive layer 50, the active layer 40 and the first semiconductor conductive layer 30 is etched to expose a portion of the first semiconductor conductive layer 30 (i.e. second portion). Next, the transparent conductive layer 60 and the second electrode 80 are sequent formed on the second semiconductor conductive layer 50, and the first electrode 70 is formed on the exposed portion of the first semiconductor conductive layer 30.

Obviously, according to the illustration of embodiments aforementioned, there may be modification and differences in the present invention. Thus, it is necessary to understand the addition of claims. In addition of detailed illustration aforementioned, the present invention may be broadly applied to other embodiments. Although the present invention has been explained in relation to its preferred embodiment, it is to be understood that other modifications and variation can be made without departing the spirit and scope of the invention as hereafter claimed.

What is claimed is:

1. A stacked structure for an optoelectronic device, comprising:
a substrate;
a buffer layer on said substrate comprising:
a first gallium nitride based compound layer on said substrate; and
a V-II group compound layer on said first gallium nitride based compound layer;
a first semiconductor conductive layer on having a first portion and a second portion on said buffer layer, wherein said first portion away from said second portion;
an active layer on said first portion of said first semiconductor conductive layer; and
a second semiconductor conductive layer on said active layer.

2. The stacked structure according to claim 1, wherein said first gallium nitride based compound layer is selected from the group consisting of: AlInN, AlGaN, InGaN and AlInGaN.

3. The stacked structure according to claim 1, wherein said V-II group compound layer includes a material of II group selected from the group consisting of: Be, Mg, Ca, Sr, Ba, Ra, Zn, Cd and Hg.

4. The stacked structure according to claim 1, wherein said V-II group compound layer includes a material of V group selected from the group consisting of: N, P, As, Sb and Bi.

5. The stacked structure according to claim 1, wherein said second gallium nitride based compound layer is selected from the group consisting of: AlGaN and GaN.

6. The stacked structure according to claim 1, wherein said active layer is selected from the group consisting of: double hetero-junction, Multi Quantum Well (MQW), and single quantum Well.

7. The stacked structure according to claim 1, further comprising a plurality of microparticles distributed between said first gallium nitride based compound layer and said active layer, so as said active layer has an uneven surface.

8. An optoelectronic device, comprising:
a first electrode;
a substrate on said first electrode;
a buffer layer on said substrate, wherein said buffer layer comprises:
a first gallium nitride based compound layer on said substrate; and
a V-II group compound layer on said first gallium nitride based compound layer;
a first semiconductor conductive layer on said buffer layer;
a second semiconductor conductive layer;
an active layer between said first semiconductor conductive layer and said second semiconductor conductive layer;
a transparent layer on said second semiconductor conductive layer; and
a second electrode on said transparent conductive layer.

9. The stacked structure according to claim 8, wherein said first gallium nitride based compound layer is selected from the group consisting of: AlInN, AlGaN, InGaN and AlInGaN.

10. The optoelectronic device according to claim 8, wherein said V-II group compound layer includes a material of II group selected from the group consisting of: Be, Mg, Ca, Sr, Ba, Ra, Zn, Cd and Hg.

11. The optoelectronic device according to claim 8, wherein said V-II group compound layer includes a material of V group selected from the group consisting of: N, P, As, Sb and Bi.

12. The optoelectronic device according to claim 8, further comprising a second gallium nitride based compound layer is on said V-II group compound layer, wherein said second gallium nitride based compound layer is selected from the group consisting of: AlGaN and GaN.

13. The optoelectronic device according to claim 8, wherein said active layer is selected from the group consisting of: double heterojunction, Multi Quantum Well (MQW) and single quantum Well.

14. An optoelectronic device, comprising:
a substrate;
a buffer layer is on said substrate, wherein said buffer layer comprises:
a first gallium nitride based compound layer on said substrate;
a V-II group compound layer is on said first gallium nitride based compound layer;
a first semiconductor conductive layer on said buffer layer, wherein said first semiconductor conductive layer having a first portion and a second portion, and said first portion away from said second portion;
a first electrode on said second portion of said first semiconductor conductive layer;
an active layer on said first portion of said first semiconductor conductive layer and away from said first electrode;
a second semiconductor conductive layer is on said active layer;
a transparent conductive layer on said active layer; and
second electrode on said transparent conductive layer.

15. The optoelectronic device according to claim 14, wherein said first gallium nitride based compound layer is selected from the group consisting of: AlInN, AlGaN, InGaN and AlInGaN.

16. The optoelectronic device according to claim 14, wherein said V-II group compound layer includes a material of II group selected from the group consisting of: Be, Mg, Ca, Sr, Ba, Ra, Zn, Cd and Hg.

17. The optoelectronic device according to claim 14, wherein said V-II group compound layer includes a material of V group selected from the group consisting of: N, P, As, Sb and Bi.

18. The optoelectronic device according to claim 14, further comprising a second gallium nitride based compound layer is formed on said V-II group compound layer.

19. The optoelectronic device according to claim 14, wherein said second gallium nitride based compound layer is selected from the group consisting of: AlGaN and GaN.

20. The optoelectronic device according to claim 14, wherein a material of said transparent conductive layer is made from a material selected from the group consisting of: Ni/Au, NiO/Au, Ta/Au, TiWN, TiN, Indium Tin Oxide, Chromium Tin Oxide, Antinomy doped Tin Oxide, Zinc Aluminum Oxide and Zinc Tin Oxide.
